(19) United States
(12) Patent Application Publication
(10) Pub. No.: US 2026/0164672 A1
(43) Pub. Date: Jun. 11, 2026

(54) ANTI-FERROMAGNETIC MAGNETIC RANDOM ACCESS MEMORY DEVICE AND MANUFACTURING METHOD THEREFOR

(71) Applicants: BEIJING INSTITUTE OF TECHNOLOGY, Beijing (CN); YANGTZE DELTA GRADUATE SCHOOL OF BIT (JIAXING), Jiaxing, Zhejiang (CN)

(72) Inventors: Shujun YE, Beijing (CN); Yeliang WANG, Beijing (CN)

(21) Appl. No.: 18/702,314

(22) PCT Filed: Mar. 28, 2023
(86) PCT No.: PCT/CN2023/084240

§ 371 Date: Apr. 17, 2024

(30) Foreign Application Priority Data
Jun. 15, 2022 (CN) 202210677080.9

(51) Int. Cl. H10B 61/00; H10N 50/01; H10N 50/10

(52) U.S. Cl. CPC H10B 61/20; H10N 50/01; H10N 50/10

(57) ABSTRACT

An anti-ferromagnetic magnetic random access memory device and a preparation method therefor are provided. The device includes a ferromagnetic thin film structure body, an anti-ferromagnetic thin film structure body, and a tunnel insulating thin film structure body sandwiched between the ferromagnetic thin film structure body and the anti-ferromagnetic thin film structure body. The preparation method for the device includes the following steps: preparing a first electrode and a first ferromagnetic thin film structure body on a substrate in sequence from bottom to top, then applying an external magnetic field to the first ferromagnetic thin film structure body; preparing a first tunnel insulating thin film structure body, an anti-ferromagnetic thin film structure body, a second tunnel insulating thin film structure body, a second ferromagnetic thin film structure body, and preparing a second electrode.

### CROSS-REFERENCE TO RELATED APPLICATION

This patent application is a national stage of International Application No. PCT/CN2023/084240, filed on Mar. 28, 2023, which claims the benefit of and priority to Chinese Patent Application No. 202210677080.9 filed with the Chinese Patent Office on Jun. 15, 2022, each of which is hereby incorporated by reference herein in its entirety.

### TECHNICAL FIELD

The present disclosure relates to the field of memory chips in integrated circuits, and in particular to an anti-ferromagnetic magnetic random access memory device and a manufacturing method therefor.

### BACKGROUND

Magnetic random access memory (MRAM) has been partially used in integrated circuits. However, the current MRAM is mainly used for storage and reading based on ferromagnet. The anti-ferromagnets have excellent characteristics that ferromagnets do not have, such as ultra-high information write-in speed at the terahertz level and resistance to external magnetic interference, the anti-ferromagnets are considered to be the most important spin electronic devices for the next generation of MRAM.

At present, anti-ferromagnet-based spin electron devices are widely studied as candidate devices for MRAM. Usually, the spin electron device can achieve information write-in by manipulating spin electrons of an anti-ferromagnet using spin orbit torque (SOT), and achieve information read by detecting an anomalous Hall effect (AHE) of the anti-ferromagnet using Hall bar. However, SOT write-in requires a large SOT channel, while AHE read usually requires a large Hall bar, so it is difficult to reduce the size of the device to less than 100 nanometers, which means that it is difficult to achieve high-density storage, that is, it is difficult to be applied in integrated circuits on a large scale.

### SUMMARY

For the disadvantages in the prior art, an objective of the present disclosure is to provide an anti-ferromagnetic magnetic random access memory device and a manufacturing method therefor, which can realize an information write-in and reading mode with reduced device size. The device provided by the solution not only can completely possess the characteristics such as ultra-high information write-in speed at terahertz level and resistance to external magnetic interference that the anti-ferromagnets have, but also can reduce the device size to about 10 nanometers, that is, high-density storage can be achieved.

The technical solution adopted by the present disclosure for solving the technical problem is as follows.

An anti-ferromagnetic magnetic random access memory device provided by the present disclosure includes a ferromagnetic thin film structure body, an anti-ferromagnetic thin film structure body, and a tunnel insulating thin film structure body sandwiched between the ferromagnetic thin film structure body and the anti-ferromagnetic thin film structure body.

In some embodiments, each of the ferromagnetic thin film structure body, the anti-ferromagnetic thin film structure body and the tunnel insulating thin film structure body may employ any one of a single-layer thin film made of a single material, and a multi-layer superimposed film made of a plurality of materials.

In some embodiments, the memory device includes a first ferromagnetic thin film structure body, a first tunnel insulating thin film structure body arranged on an upper part of the first ferromagnetic thin film structure body, an anti-ferromagnetic thin film structure body arranged on an upper part of the first tunnel insulating thin film structure body, a second tunnel insulating thin film structure body arranged on an upper part of the anti-ferromagnetic thin film structure body, and a second ferromagnetic thin film structure body arranged on an upper part of the second tunnel insulating thin film structure body; spin electrons of the first ferromagnetic thin film structure body and the second ferromagnetic thin film structure body are fixed in opposite directions. Each of the first ferromagnetic thin film structure body, the first tunnel insulating thin film structure body, the anti-ferromagnetic thin film structure body, the second tunnel insulating thin film structure body and the second ferromagnetic thin film structure body may employ any one of a single-layer thin film made of a single material, and a multi-layer superimposed film made of a plurality of materials.

In some embodiments, a voltage control magnetic anisotropy (VCMA) electrode capable of applying a voltage to the anti-ferromagnetic thin film structure body for controlling magnetic anisotropy is provided around a side surface of the anti-ferromagnetic thin film structure body, and the VCMA electrode may employ any one of a multilayer heterostructure made of different materials and a single structure made of a same material.

In some embodiments, insulating layer thin film is provided around the side surface of the anti-ferromagnetic thin film structure body, and the VCMA electrode may be connected to an outer surface of the insulating layer thin film by any one of connection modes, including completely surrounding the outer surface of the insulating layer thin film, partially surrounding the outer surface of the insulating layer thin film, and partially contacting with the outer surface of the insulating layer thin film.

In some embodiments, the anti-ferromagnetic thin film structure body may be replaced with a ferrimagnetic thin film structure body, the ferrimagnetic thin film structure body employs any one of a single-layer thin film made of a single material and a multi-layer superimposed film made of a plurality of materials.

A manufacturing method for an anti-ferromagnetic magnetic random access memory device includes following steps of:
preparing a first electrode on a substrate, preparing a first ferromagnetic thin film structure body on the prepared first electrode, applying an external magnetic field to arrange spin electrons of the first ferromagnetic thin film structure body in any direction; then, preparing a first tunnel insulating thin film structure body on the prepared first ferromagnetic thin film structure body, preparing the anti-ferromagnetic thin film structure body on the first tunnel insulating thin film structure body, preparing a second tunnel insulating thin film structure body on the anti-ferromagnetic thin film structure body, preparing a second ferromagnetic thin film structure body on the second tunnel insulating thin film structure body, and applying an external magnetic field to arrange spin electrons of the second ferromagnetic thin film structure body in a direction opposite to that of the spin electrons of the first ferromagnetic thin film structure body; and finally, preparing a second electrode on the second ferromagnetic thin film structure body.

A manufacturing method for an anti-ferromagnetic magnetic random access memory device includes following steps of:
(1.1) preparing the first electrode and a multi-layer thin film structure composed of the ferromagnetic thin film structure body, the tunnel insulating thin film structure body and the anti-ferromagnetic thin film structure body, and etching the multi-layer thin film structure with a semiconductor etching technology to form an anti-ferromagnetic device, and preparing an insulating layer thin film on an outer surface of the anti-ferromagnetic device;
(1.2) depositing an insulator isolation layer on a part of the anti-ferromagnetic thin film structure body of the anti-ferromagnetic device that needs not to be applied by a voltage;
(1.3) depositing a sacrificial layer which has a different etching selectivity ratio from that of the insulator isolation layer in Step (1.2) and is able to be selectively etched away at a position of the anti-ferromagnetic device that needs to be applied by the voltage, where the sacrificial layer is able to be directly deposited to a required thickness, or deposited to a thickness exceeding that of the anti-ferromagnetic thin film structure body and then etched back to the required thickness, such that a thickness of a etched sacrificial layer is less than or equal to that of the anti-ferromagnetic thin film structure body;
(1.4) depositing a layer of insulator isolation layer on a top and a side surface of the sacrificial layer obtained in Step (1.3);
(1.5) depositing a second electrode material on one end of the ferromagnetic thin film structure body that needs to be applied by the voltage, and performing an etching processing on the second electrode, such that the prepared second electrode has a non-overlapping part with the sacrificial layer in Step (1.3) in a top view angle, and then covering the non-overlapping part with an insulator isolation layer and polishing the insulator isolation layer;
(1.6) etching and punching a hole at a position of the sacrificial layer which is not overlapped with the second electrode in Step (1.5) until the hole is in contact with the sacrificial layer, and etching away the sacrificial layer;
(1.7) depositing a VCMA electrode at a position where the sacrificial layer is etched away in Step (1.6); and
(1.8) etching away redundant VCMA electrode material at a position of the hole in Step (1.6), depositing a wire for connecting the VCMA electrode material to an exterior to obtain the VCMA electrode capable of applying the voltage to the anti-ferromagnetic thin film structure body.

In the manufacturing method for an anti-ferromagnetic magnetic random access memory device, the VCMA electrode may be prepared according to following steps comprising:
(2.1) depositing the insulating layer thin film on a surface of the anti-ferromagnetic device;
(2.2) depositing the insulator isolation layer on a part of the anti-ferromagnetic device that needs not to be applied by the voltage;
(2.3) depositing the VCMA electrode on an outer side surface of the insulating layer thin film corresponding to a side surface of the anti-ferromagnetic thin film structure body of the anti-ferromagnetic device, where the VCMA electrode is able to be directly deposited to the required thickness, or deposited to a thickness exceeding that of the anti-ferromagnetic thin film structure body and then etched back to the required thickness, such that the thickness of the deposited VCMA electrode is less than or equal to that of the anti-ferromagnetic thin film structure body;
(2.4) performing the etching processing on the VCMA electrode deposited in Step (2.3) to form a required pattern; and
(2.5) depositing another insulator isolation layer on a top and outside surface of the VCMA electrode obtained in Step (2.4) and an outer surface of the insulating layer thin film exposed from a top of the VCMA electrode.

In the manufacturing method for the anti-ferromagnetic magnetic random access memory device, the anti-ferromagnetic thin film structure body may be replaced with a ferrimagnetic thin film structure body, and the ferrimagnetic thin film structure body may employ any one of a single-layer thin film made of a single material and a multi-layer superimposed film made of a plurality of materials.

The present disclosure has the following beneficial effects by adopting the above-mentioned technical solution.

The anti-ferromagnetic magnetic random access memory device and a manufacturing method therefor provided by the present disclosure may achieve an information write-in and read mode with reduced device size. The device not only can completely possess the characteristics such as ultra-high information write-in speed at terahertz level and resistance to external magnetic interference that the anti-ferromagnets have, but also can reduce the device size to about 10 nanometers, that is, high-density storage can be achieved.

Due to the fact that upper and lower interfaces of the anti-ferromagnetic thin film structure body have unpaired spin electrons and show weak magnetism in a nano-scale thin film, the anti-ferromagnetic thin film structure body may be considered as a ferromagnet with small magnetization and great coercivity. In addition, the ferrimagnetic thin film structure body has properties similar to those of the anti-ferromagnetic thin film structure body, and shows weak ferromagnetism at the same time, so the storing, reading and writing based on the anti-ferromagnetic thin film structure body in the present disclosure are also applicable to ferrimagnets.

The spin electron direction of the anti-ferromagnetic thin film structure body is used for information storage, and the information read can be achieved through the synergistic effect of different resistance of the anti-ferromagnetic thin film structure body perpendicular to a film surface in different spin electron directions (i.e. magnetoresistance effect) and different resistance of a device composed of the anti-ferromagnetic thin film structure body, the tunnel insulating thin film structure body and the ferromagnetic thin film structure body in different spin electron directions. The information write-in can be achieved by the spin transfer torque (STT) acting on spin electrons of the anti-ferromagnetic thin film structure body through the tunnel insulating thin film structure by two ferromagnets with opposite spin electron directions above and below the anti-ferromagnetic thin film structure body. Different from the write-in principle of writing information to magnetic tunnel junction (MTJ) using STT, in the present disclosure, from which end of the ferromagnetic thin film structure body the current is introduced, STT spin transfer may be performed on the anti-ferromagnetic thin film structure body in the spin electron direction of the ferromagnetic thin film structure body at the end for information write-in. Because the spin electron directions of the ferromagnetic thin film structure bodies arranged at two ends of the anti-ferromagnetic thin film structure body are opposite, the spin electron directions of the anti-ferromagnetic thin film structure body may change when write-in current is introduced from two ends. The present disclosure has a structure similar to STT-MTJ, so the device size is expected to below 10 nanometers.

The present disclosure not only can possess the characteristics such as ultra-high information write-in speed at terahertz level and resistance to external magnetic interference that the anti-ferromagnetic thin film structure body has, but also solves the problem that the spin electron device based on the anti-ferromagnetic thin film structure body currently for MRAM is too large to be applied to an integrated circuit on a large scale due to the traditional reading and writing methods (such as using spin orbit torque (SOT) for write-in, using anomalous Hall effect (AHE) for reading and the like).

### BRIEF DESCRIPTION OF THE DRAWINGS

To describe the technical solutions in the embodiments of the present disclosure or in the prior art more clearly, the accompanying drawings that need to be used in the embodiments will be briefly introduced hereinafter. Apparently, the accompanying drawings in the following description are merely some embodiments of the present disclosure, for those ordinarily skilled in the art, other drawings may also be obtained according to these drawings without making creative efforts.

FIG. 1 is a structural schematic diagram of an anti-ferromagnetic magnetic random access memory device according to Embodiment 1 of the present disclosure;

FIG. 2 is a structural schematic diagram of the anti-ferromagnetic magnetic random access memory device according to Embodiment 2 of the present disclosure;

FIG. 3A-FIG. 3F are flowcharts of a preparation method for a first part of the anti-ferromagnetic magnetic random access memory device according to embodiments of the present disclosure, where FIG. 3A is a schematic diagram of a preparation of a first electrode and a first ferromagnetic thin film structure body, FIG. 3B is a schematic diagram showing that a magnetic field is applied to a first ferromagnetic thin film structure body prepared in FIG. 3A to fix a spin electron direction of the first ferromagnetic thin film structure body; FIG. 3C is a schematic diagram of a preparation of a first tunnel insulating thin film structure body; FIG. 3D is a schematic diagram of a preparation of an anti-ferromagnetic thin film structure body or a ferrimagnetic thin film structure body; FIG. 3E is a schematic diagram of a preparation of a second tunnel insulating thin film structure body; and FIG. 3F is a schematic diagram of a preparation of a first ferromagnetic thin film structure body;

FIG. 4A-FIG. 4C are flowcharts of a preparation method for a second part of the anti-ferromagnetic magnetic random access memory device according to embodiments of the present disclosure, where FIG. 4A is a schematic diagram of application of an external magnetic field opposite to that in FIG. 3B to the structure body prepared in FIG. 3F; FIG. 4B is a schematic diagram showing that a spin electron direction of the second ferromagnetic thin film structure body is fixed and opposite to that of the first ferromagnetic thin film structure body in FIG. 3B; and FIG. 4C is a schematic diagram of an anti-ferromagnetic device processed by semiconductor etching related technologies;

FIG. 5A-FIG. 5E are flowcharts of a preparation method for a third part of the anti-ferromagnetic magnetic random access memory device according to embodiments of the present disclosure, where FIG. 5A is a schematic diagram of a deposition of an insulating layer thin film; FIG. 5B is a schematic diagram of a deposition of a first insulating isolation layer; FIG. 5C is a schematic diagram of a deposition of a sacrificial layer; FIG. 5D is a schematic diagram showing etching a thickness of a sacrificial layer back to a required thickness; and FIG. 5E is a schematic diagram showing etching the sacrificial layer to a desired shape by semiconductor etching related technologies;

FIG. 6A-FIG. 6F are flowcharts of a preparation method for a fourth part of the anti-ferromagnetic magnetic random access memory device according to embodiments of the present disclosure, where FIG. 6A is a schematic diagram of filling and polishing of a second insulator isolation layer; FIG. 6B is a schematic diagram showing polishing a second insulator isolation layer until the top of a second ferromagnetic thin film structure body is exposed; FIG. 6C is a schematic diagram of a deposition of a second electrode; FIG. 6D is a schematic diagram showing etching a second electrode to a desired shape; FIG. 6E is a schematic diagram of filling and polishing of a third insulator isolation layer; and FIG. 6F is a schematic diagram showing punching;

FIG. 7A-FIG. 7C are flowcharts of a preparation method for a fifth part of the anti-ferromagnetic magnetic random access memory device according to embodiments of the present disclosure, where FIG. 7A is a schematic diagram showing that the sacrificial layer is etched away; FIG. 7B is a schematic diagram of a deposition of a VCMA electrode; FIG. 7C is a schematic diagram showing that the VCMA electrode at a hole position of FIG. 6F is etched away and a wire is deposited;

FIG. 8A-FIG. 8D are schematic diagrams of a preparation process for the VCMA electrode in a preparation method for the anti-ferromagnetic magnetic random access memory device according to embodiments of the present disclosure, where FIG. 8A is a schematic diagram showing that a fourth insulator isolation layer is deposited on a position at the bottom of an anti-ferromagnetic device that does not require the VCMA electrode after an insulating layer thin film is deposited on an outer surface of the anti-ferromagnetic device; FIG. 8B is a schematic diagram showing that the VCMA electrode is deposited until a thickness of the VCMA electrode exceeds that of the anti-ferromagnetic device; FIG. 8C is a schematic diagram showing that the VCMA electrode is etched back to the thickness not greater than that of the anti-ferromagnetic thin film structure body; and FIG. 8D is a schematic diagram of a deposition of a fifth insulator isolation layer; and

FIG. 9A-FIG. 9D are schematic diagrams of another preparation process for the VCMA electrode in a preparation method for the anti-ferromagnetic magnetic random access memory device according to embodiments of the present disclosure, where FIG. 9A is a schematic diagram showing that a sixth insulator isolation layer is deposited on a position at the bottom of the anti-ferromagnetic device that does not require the VCMA electrode after the insulating layer thin film is deposited on the outer surface of the anti-ferromagnetic device; FIG. 9B is a schematic diagram showing that the VCMA electrode is deposited on an outer surface of the structure body formed in FIG. 9A; FIG. 9C is a schematic diagram showing that a portion of the VCMA electrode exceeding the thickness of the anti-ferromagnetic thin film structure body is etched away; and FIG. 9D is a schematic diagram of a deposition of a seventh insulator isolation layer.

### DETAILED DESCRIPTION OF THE EMBODIMENTS

The technical solutions in the embodiments of the present disclosure will be clearly and completely described with reference to the accompanying drawings in the embodiments of the present disclosure hereinafter. Apparently, the described embodiments are only some embodiments of the present disclosure, rather than all of the embodiments. Based on the embodiments in the present disclosure, all other embodiments obtained by those ordinarily skilled in the art without making creative efforts belong to the scope of protection of the present disclosure.

In the description of the present disclosure, it needs to be understood that the orientation or positional relationship indicated by terms such as “upper”, “lower”, “horizontal”, “inside” and “outside”, “top” and “bottom” is based on the orientation or positional relationship shown in the drawings, which is only for convenience of description of the present disclosure and simplification of description rather than indicating or implying that the apparatus or element referred to has to possess a particular orientation, be constructed and operated in a particular orientation, and thus are not to be construed as limiting the present disclosure.

In the present disclosure, it should be noted that, unless expressly specified and limited otherwise, the terms “form” and “connect” should be understood broadly, e.g., may be either a fixed connection or a detachable connection, or a connection in one piece; may be a direct connection or an indirect connection through an intermediate medium. For those ordinarily skilled in the art, the specific meanings of the above terms in the utility model may be understood on a case-by-case basis.

The present disclosure is further described below with reference to specific embodiments.

### Embodiment 1

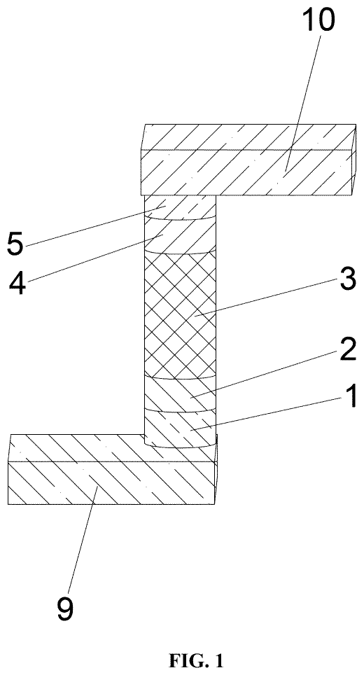

As shown in FIG. 1, an anti-ferromagnetic magnetic random access memory device provided by Embodiment 1 of the present disclosure includes a first ferromagnetic thin film structure body 1, a first tunnel insulating thin film structure body 2 arranged on an upper part of the first ferromagnetic thin film structure body 1, an anti-ferromagnetic thin film structure body 3 arranged on an upper part of the first tunnel insulating thin film structure body 2, a second tunnel insulating thin film structure body 4 arranged on an upper part of the anti-ferromagnetic thin film structure body 3, and a second ferromagnetic thin film structure body 5 arranged on an upper part of the second tunnel insulating thin film structure body 4.

Each of the first ferromagnetic thin film structure body 1 and the second ferromagnetic thin film structure body 5 may be composed of a layer of ferromagnetic thin film, multiple layers of ferromagnetic thin films, a layer of ferromagnetic thin film and a layer of non-ferromagnetic thin film, or multiple layers of ferromagnetic thin films and multiple layers of non-ferromagnetic thin films, where the ferromagnetic thin film is generally CoFeB alloy, etc. Spin electrons of the first ferromagnetic thin film structure body 1 and the second ferromagnetic thin film structure body 5 are fixed in opposite directions.

Each of the first tunnel insulating thin film structure body 2 and the second tunnel insulating thin film structure body 4 is a non-magnetic thin film structure body, which may be any one of a multi-layer heterogeneous structure made of different materials, and a single structure made of the same material; the non-magnetic thin film structure body is a substance other than magnetism, where the tunnel insulating thin film is usually MgO, etc.

The bottom of the first ferromagnetic thin film structure body 1 is provided with a first electrode 9, and the top of the second ferromagnetic thin film structure body 5 is provided with a second electrode 10.

The anti-ferromagnetic thin film structure body 3 may be composed of a layer of anti-ferromagnetic thin film, multiple layers of anti-ferromagnetic thin films, or a layer of anti-ferromagnetic thin film and a layer of non-magnetic thin film, or multiple layers of anti-ferromagnetic thin films and multiple layers of non-magnetic thin films., where the anti-ferromagnetic thin film structure body 3 is generally Mn₃X series alloy (e.g., Mn₃Sn etc.), CuMnAs series compound, or anti-ferromagnetic oxides (e.g., Cr₂O₃, NiO) etc.

The anti-ferromagnetic thin film structure body 3 may also be a ferrimagnetic thin film structure body, which may be made of a layer of ferrimagnetic thin film, multiple layers of ferrimagnetic thin films, a layer of ferrimagnetic thin film and a layer of non-magnetic thin film, or multiple layers of ferrimagnetic thin films and multiple layers of non-magnetic thin films.

### Embodiment 2

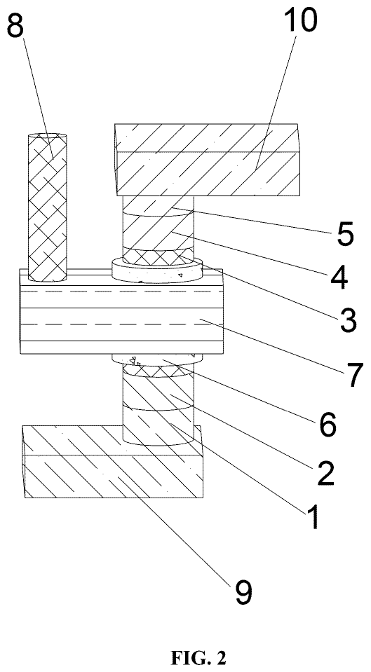

As shown in FIG. 2, the difference of the structure in Embodiment 2 according to the present disclosure from that in Embodiment 1 is that an insulating layer thin film 6 is also provided around a side surface of the anti-ferromagnetic thin film structure body 3, and the outer surface of the insulating layer thin film 6 is surrounded by a VCMA electrode 7 capable of applying a voltage to the anti-ferromagnetic thin film structure body 3 for controlling magnetic anisotropy. One end of the VCMA electrode 7 is arranged around the outer surface of the insulating layer thin film 6, and the other end of the VCMA electrode 7 extends away from the insulating layer thin film 6, and an extension part is provided with a wire 8 for connecting the VCMA electrode to the exterior.

The VCMA electrode 7 may be any one of a multilayer heterostructure made of different materials, and a single structure made of the same material. The VCMA electrode 7 may be connected to an outer surface of the insulating layer thin film 6 by any one of connection modes, such as completely surrounding the outer surface of the insulating layer thin film 6, partially surrounding the outer surface of the insulating layer thin film 6, and partially contacting with the outer surface of the insulating layer thin film 6. The VCMA electrode 7 capable of applying a voltage to the anti-ferromagnetic thin film structure body 3 for controlling magnetic anisotropy is arranged on a side surface of the anti-ferromagnetic thin film structure body 3 to assist the first ferromagnetic thin film structure body 1 or the second ferromagnetic thin film structure body 5 to perform STT write-in mode on the anti-ferromagnetic thin film structure body 3, thereby reducing the energy consumption for information write-in.

The material of each of the first ferromagnetic thin film structure body 1, the first tunnel insulating thin film structure body 2, the anti-ferromagnetic thin film structure body 3, the second tunnel insulating thin film structure body 4, the second ferromagnetic thin film structure body 5, the insulating layer thin film 6 and the VCMA electrode 7 may be doped with other materials to improve the related performance.

A preparation method for an anti-ferromagnetic magnetic random access memory device in the present disclosure mainly includes the following steps:
preparing a first electrode 9 on a substrate 01, preparing the first ferromagnetic thin film structure body 1 on the prepared first electrode 9, applying an external magnetic field to make spin electrons of the first ferromagnetic thin film structure body 1 arranged in any direction, then, preparing a first tunnel insulating thin film structure body 2 on the prepared first ferromagnetic thin film structure body 1, preparing any one of an anti-ferromagnetic thin film structure body 3 and a ferrimagnetic thin film structure body on the first tunnel insulating thin film structure body 2, preparing a second tunnel insulating thin film structure body 4 on any one of the anti-ferromagnetic thin film structure body 3 and the ferrimagnetic thin film structure body, preparing a second ferromagnetic thin film structure body 5 on the second tunnel insulating thin film structure body 4, and applying an external magnetic field to make spin electrons of the second ferromagnetic thin film structure body 5 arranged in a direction opposite to that of the spin electrons of the first ferromagnetic thin film structure body 1, and finally, preparing a second electrode 10 on the second ferromagnetic thin film structure body 5.

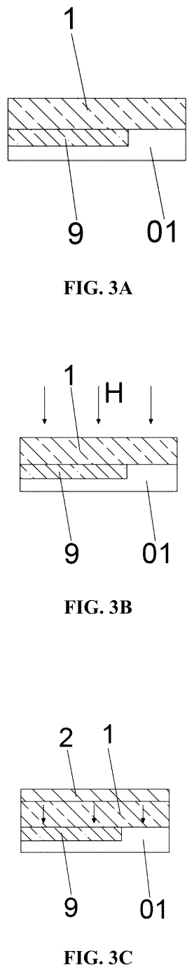

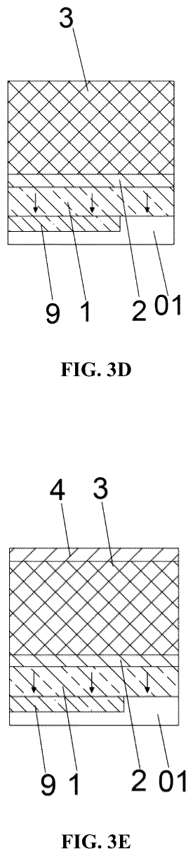

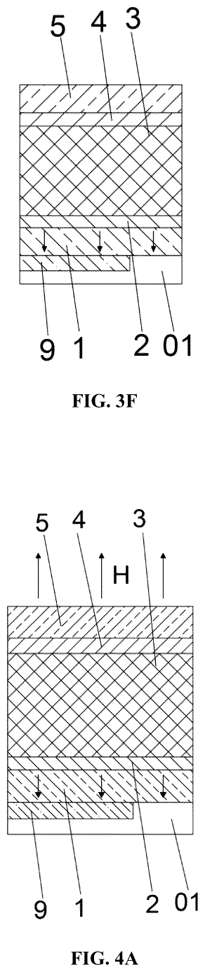

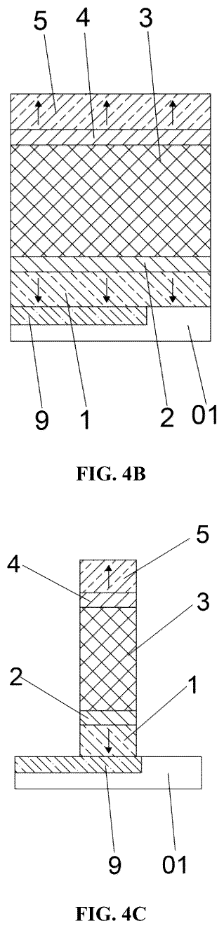

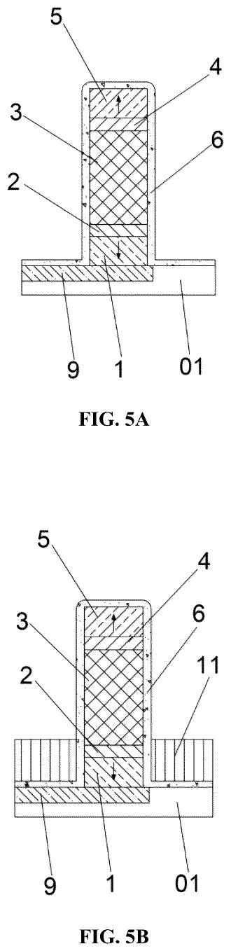

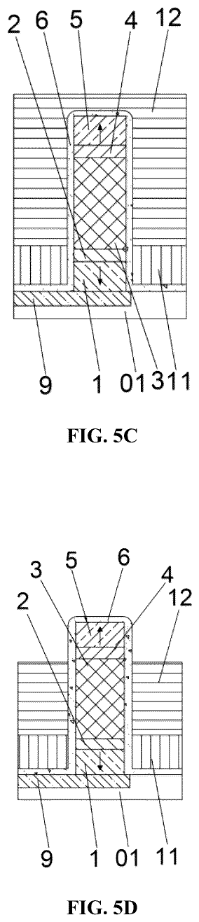

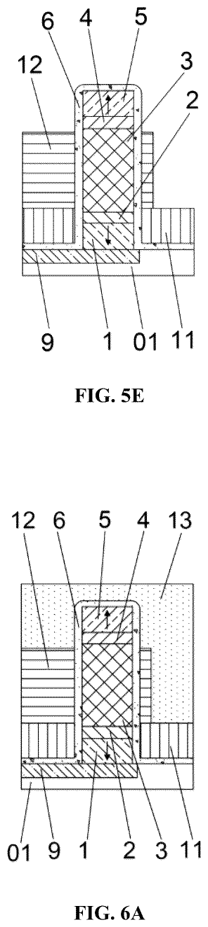

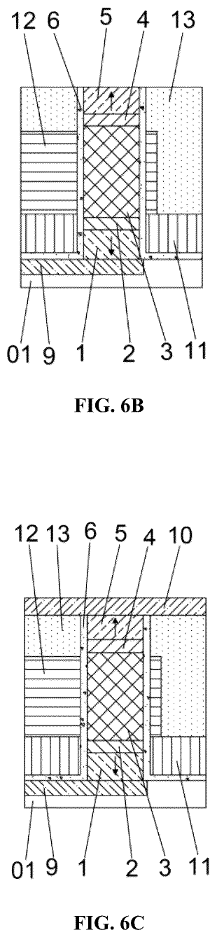

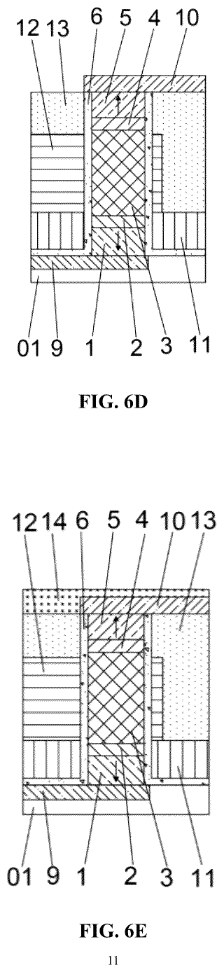

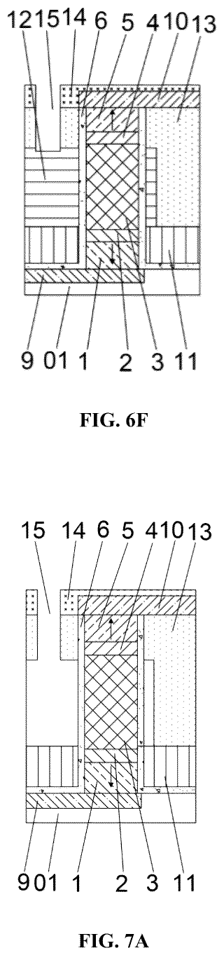

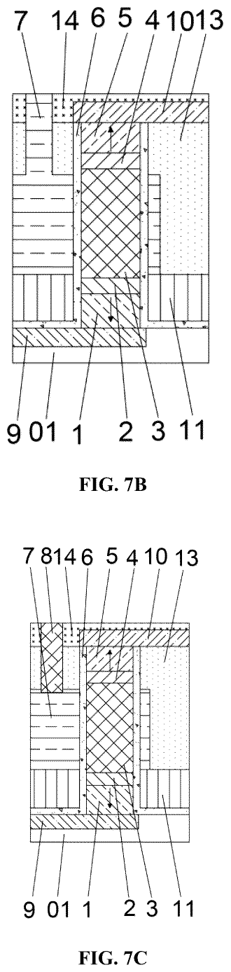

A preparation method for an anti-ferromagnetic magnetic random access memory device in the present disclosure specifically includes the following main steps.
(1.1) As shown in FIG. 3A, a first electrode 9 is prepared on a substrate 01. As shown in FIG. 3B, a first ferromagnetic thin film structure body 1 is prepared on the first electrode 9, and then a downward magnetic field is applied to the first ferromagnetic thin film structure body 1. As shown in FIG. 3C, a first tunnel insulating thin film structure body 2 is prepared on the upper part of the first ferromagnetic thin film structure body 1. As shown in FIG. 3D, an anti-ferromagnetic thin film structure body 3 (or a ferrimagnetic thin film structure body) is prepared on the first tunnel insulating thin film structure body 2. As shown in FIG. 3E, a second tunnel insulating thin film structure body 4 is prepared on an upper part of the anti-ferromagnetic thin film structure body 3. As shown in FIG. 3F, a second ferromagnetic thin film structure body 5 is prepared on an upper part of the second tunnel insulating thin film structure body 4. As shown in FIG. 4A and FIG. 4B, an upward magnetic field is applied to the second ferromagnetic thin film structure body 5. As shown in FIG. 4C, the first ferromagnetic thin film structure body 1, the first tunnel insulating thin film structure body 2, the anti-ferromagnetic thin film structure body 3, the second tunnel insulating thin film structure body 4 and the second ferromagnetic thin film structure body 5 are etched using semiconductor etching technology to form an anti-ferromagnetic device (the shape of the anti-ferromagnetic device is ideally cylindrical, but actually frustum cone-shaped in general). As shown in FIG. 5A, an insulating layer thin film 6 is prepared on an outer surface of the anti-ferromagnetic device. The directions of magnetic fields applied to the first ferromagnetic thin film structure body 1 and the second ferromagnetic thin film structure body 5 are only required to ensure that the spin directions of the first ferromagnetic thin film structure body 1 and the second ferromagnetic thin film structure body 5 are opposite.
(1.2) As shown in FIG. 5B, a first insulator isolation layer 11 is deposited on a part of the anti-ferromagnetic device that needs not to be applied by a voltage;
(1.3) As shown in FIG. 5C, a sacrificial layer 12 which has a different etching selectivity ratio from that of the first insulator isolation layer 11 in step (1.2) and may be selectively etched away is deposited at a position of the anti-ferromagnetic device that needs to be applied by the voltage As shown in FIG. 5D, the sacrificial layer 12 may be directly deposited to a required thickness, or may be deposited to a thickness exceeding that of the anti-ferromagnetic thin film structure body 3 and then etched back to the required thickness, so that the thickness of the etched sacrificial layer is less than or equal to that of the anti-ferromagnetic thin film structure body 3.
(1.4) As shown in FIG. 5E, the sacrificial layer 12 obtained in Step (1.3) is etched to form a required pattern. As shown in FIG. 5E, the sacrificial layer 12 obtained in Step (1.3) may also not be etched.
(1.5) As shown in FIG. 6A, a second insulator isolation layer 13 is deposited on the top and the side surface of the sacrificial layer 12 obtained in Step (1.4). As shown in FIG. 6B, the upper part of the second insulator isolation layer 13 is polished until the top of the second ferromagnetic thin film structure body 5 is exposed.
(1.6) As shown in FIG. 6C, a second electrode 10 is deposited on the upper part of the second ferromagnetic thin film structure body 5 that needs to be applied by the voltage. As shown in FIG. 6D, the second electrode 10 after being etched, has a non-overlapping part with the sacrificial layer 12 in Step (1.4) in a top view angle. As shown in FIG. 6E, the non-overlapping part is covered with a third insulator isolation layer 14 and polished.
(1.7) As shown in FIG. 6F, a hole 15 is etched and punched at a position of the third Substitute Specification-Clean Version insulator isolation layer 14 which is not overlapped with the second electrode 10 in Step (1.6) until the hole is in contact with the sacrificial layer 12. As shown in FIG. 7A, the sacrificial layer 12 is etched away.
(1.8) As shown in FIG. 7B, a VCMA electrode 7 is deposited at a position where the sacrificial layer 12 is etched away in Step (1.7).
(1.9) As shown in FIG. 7C, redundant VCMA electrode 7 at a position of the hole 15 in Step (1.7) is etched away, and a wire 8 for connecting the VCMA electrode 7 to the outside is deposited, and finally, an VCMA electrode 7 capable of applying a voltage to the anti-ferromagnetic thin film structure body is formed.

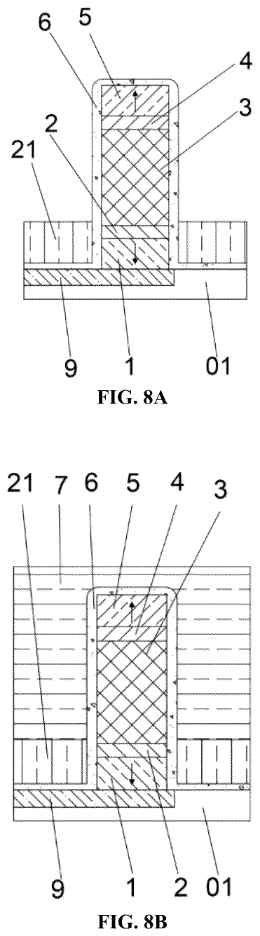

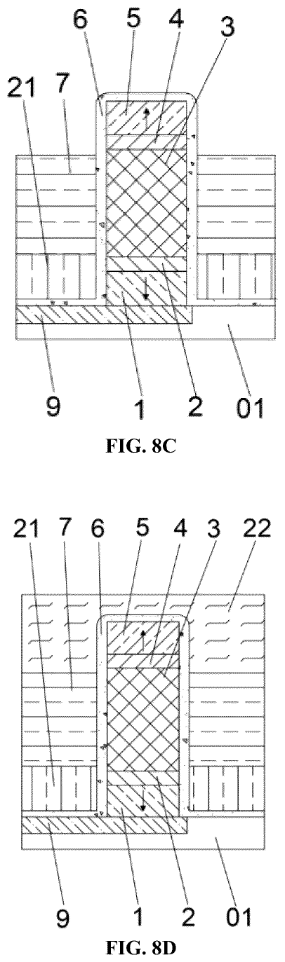

As shown in FIG. 8A-FIG. 8D, a preparation method for an anti-ferromagnetic magnetic random access memory device in the present disclosure may also include the following steps.
(2.1) As shown in FIG. 5A, an insulating layer thin film 6 is deposited on a surface of an anti-ferromagnetic device.
(2.2) As shown in FIG. 8A, a fourth insulator isolation layer 21 is deposited on a part of the anti-ferromagnetic device that needs not to be applied by the voltage;
(2.3) As shown in FIG. 8B, a VCMA electrode is deposited on an outer side surface of the insulating layer thin film 6 corresponding to a side surface of an anti-ferromagnetic thin film structure body 3 of the anti-ferromagnetic device. As shown in FIG. 8C, the VCMA electrode 7 may be directly deposited to a required thickness. As shown in FIG. 8B, the VCMA electrode 7 may be etched back to the required thickness after being deposited to a thickness exceeding the thickness of the anti-ferromagnetic device, so that the thickness of the deposited VCMA electrode is less than or equal to the thickness of the anti-ferromagnetic thin film structure body.
(2.4) As shown in FIG. 8C, the VCMA electrode 7 deposited in Step (2.3) is etched to form a required pattern.
(2.5) As shown in FIG. 8D, a fifth insulator isolation layer 22 is deposited on an outer surface of the insulating layer thin film 6 above the VCMA electrode 7 obtained in Step (2.4).

The anti-ferromagnetic thin film structure body may be replaced with a ferrimagnetic thin film structure body, and an outer side surface of the ferrimagnetic thin film structure body is provided with a VCMA electrode capable of applying a voltage to the ferrimagnetic thin film structure body for controlling the magnetic anisotropy. The ferrimagnetic thin film structure body may employ any one of a single-layer thin film made of a single material, or a multi-layer superimposed film made of multiple materials.

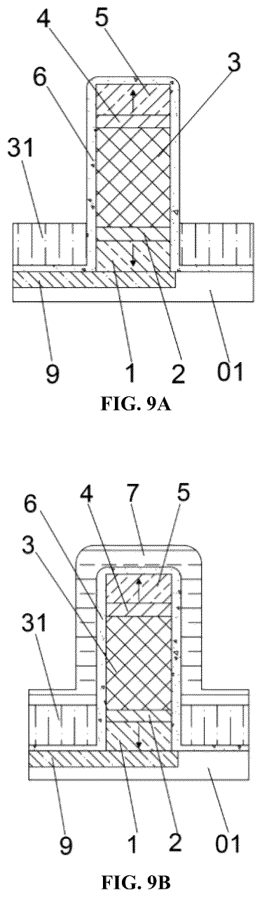

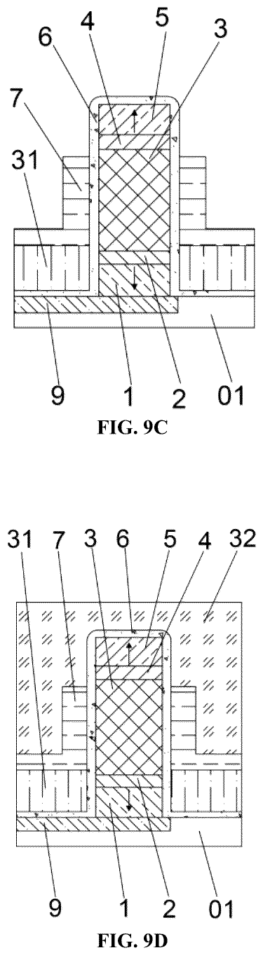

A preparation method for an anti-ferromagnetic magnetic random access memory device in the present disclosure may also include the following steps.
(3.1) As shown in FIG. 5A, an insulating layer thin film 6 is deposited on a surface of the anti-ferromagnetic device.
(3.2) As shown in FIG. 9A, a sixth insulator isolation layer 31 is deposited on a part of the anti-ferromagnetic device that needs not to be applied by the voltage.
(3.3) As shown in FIG. 9B, a VCMA electrode 7 is deposited on an outer side surface of the insulating layer thin film 6 corresponding to a side surface of an anti-ferromagnetic thin film structure body 3 of the anti-ferromagnetic device. As shown in FIG. 9C, the VCMA electrode 7 may be directly deposited to a required thickness, or may be etched back to the required thickness after being deposited to a thickness exceeding the thickness of the anti-ferromagnetic device, so that the thickness of the thickest part of the deposited VCMA electrode is less than or equal to the thickness of the anti-ferromagnetic thin film structure body.
(3.4) As shown in FIG. 9C, the VCMA electrode 7 deposited in Step (3.3) is etched to form a required pattern.
(3.5) As shown in FIG. 9D, a seventh insulator isolation layer 32 is deposited on the top and outside surface of the VCMA electrode 7 obtained in Step (3.4) and the outer surface of the insulating layer thin film 6 exposed from the top of the VCMA electrode 7.

The anti-ferromagnetic magnetic random access memory device and a manufacturing method therefor provided by the present disclosure may achieve an information write-in and read mode with reduced device size, which not only completely possess the characteristics of anti-ferromagnets such as ultra-high information write-in speed at terahertz level and resistance to external magnetic interference, but also can reduce the device size to about 10 nanometers, that is, high-density storage can be achieved.

Specific examples are used herein for illustration of the principles and implementation methods of the present disclosure, the description of the above-mentioned embodiments is merely used to help illustrate the method and core principles thereof in the present disclosure; In addition, those of ordinarily skilled in the art can make various modifications in terms of specific embodiments and scope of application in accordance with the teachings of the present disclosure. In conclusion, the content of this specification should not be understood as the limitation to the present disclosure.

The embodiments of the present disclosure are described above with reference to the drawings, but the present disclosure is not limited to the above-mentioned specific embodiments, the above-mentioned specific embodiments are only schematic, not restrictive, under the inspiration of the present disclosure, those of ordinarily skilled in the art can also make many forms without departing from the spirit of the present disclosure and the claimed scope of claims, which are all within the protection of the present disclosure.

1. An anti-ferromagnetic magnetic random access memory device, comprising a ferromagnetic thin film structure body, an anti-ferromagnetic thin film structure body, and a tunnel insulating thin film structure body sandwiched between the ferromagnetic thin film structure body and the anti-ferromagnetic thin film structure body.

2. The anti-ferromagnetic magnetic random access memory device according to claim 1, wherein each of the ferromagnetic thin film structure body, the anti-ferromagnetic thin film structure body and the tunnel insulating thin film structure body employs any one of a single-layer thin film made of a single material and a multi-layer superimposed film made of a plurality of materials.

3. The anti-ferromagnetic magnetic random access memory device according to claim 1, wherein the memory device comprises a first ferromagnetic thin film structure body, a first tunnel insulating thin film structure body arranged on an upper part of the first ferromagnetic thin film structure body, an anti-ferromagnetic thin film structure body arranged on an upper part of the first tunnel insulating thin film structure body, a second tunnel insulating thin film structure body arranged on an upper part of the anti-ferromagnetic thin film structure body, and a second ferromagnetic thin film structure body arranged on an upper part of the second tunnel insulating thin film structure body; spin electrons of the first ferromagnetic thin film structure body and the second ferromagnetic thin film structure body are fixed in opposite directions; each of the first ferromagnetic thin film structure body, the first tunnel insulating thin film structure body, the anti-ferromagnetic thin film structure body, the second tunnel insulating thin film structure body and the second ferromagnetic thin film structure body employs any one of a single-layer thin film made of a single material and a multi-layer superimposed film made of a plurality of materials.

4. The anti-ferromagnetic magnetic random access memory device according to claim 1, wherein a voltage control magnetic anisotropy (VCMA) electrode capable of applying a voltage to the anti-ferromagnetic thin film structure body for controlling magnetic anisotropy is provided around a side surface of the anti-ferromagnetic thin film structure body, and the VCMA electrode employs any one of a multilayer heterostructure made of different materials and a single structure made of a same material.

5. The anti-ferromagnetic magnetic random access memory device according to claim 4, wherein an insulating layer thin film is provided around the side surface of the anti-ferromagnetic thin film structure body, and the VCMA electrode is connected to an outer surface of the insulating layer thin film by any one of connection modes, comprising completely surrounding the outer surface of the insulating layer thin film, partially surrounding the outer surface of the insulating layer thin film, and partially contacting with the outer surface of the insulating layer thin film.

6. The anti-ferromagnetic magnetic random access memory device according to claim 1, wherein the anti-ferromagnetic thin film structure body is able to be replaced with a ferrimagnetic thin film structure body, the ferrimagnetic thin film structure body employs any one of a single-layer thin film made of a single material and a multi-layer superimposed film made of a plurality of materials.

7. A manufacturing method for the anti-ferromagnetic magnetic random access memory device according to claim 1, comprising following steps of:
preparing a first electrode on a substrate, preparing a first ferromagnetic thin film structure body on the prepared first electrode, applying an external magnetic field to arrange spin electrons of the first ferromagnetic thin film structure body in any direction; preparing a first tunnel insulating thin film structure body on the prepared first ferromagnetic thin film structure body, preparing the anti-ferromagnetic thin film structure body on the first tunnel insulating thin film structure body, preparing a second tunnel insulating thin film structure body on the anti-ferromagnetic thin film structure body, preparing a second ferromagnetic thin film structure body on the second tunnel insulating thin film structure body, and applying an external magnetic field to arrange spin electrons of the second ferromagnetic thin film structure body in a direction opposite to that of the spin electrons of the first ferromagnetic thin film structure body; and
preparing a second electrode on the second ferromagnetic thin film structure body.

8. The manufacturing method according to claim 7, wherein the preparing a second electrode on the second ferromagnetic thin film structure body comprises following steps of:
(1.1) preparing the first electrode and a multi-layer thin film structure composed of the ferromagnetic thin film structure body, the tunnel insulating thin film structure body and the anti-ferromagnetic thin film structure body, and etching the multi-layer thin film structure with a semiconductor etching technology to form an anti-ferromagnetic device, and preparing an insulating layer thin film on an outer surface of the anti-ferromagnetic device;
(1.2) depositing an insulator isolation layer on a part of the anti-ferromagnetic thin film structure body of the anti-ferromagnetic device that needs not to be applied by a voltage;
(1.3) depositing a sacrificial layer which has a different etching selectivity ratio from that of the insulator isolation layer in Step (1.2) and is able to be selectively etched away at a position of the anti-ferromagnetic device that needs to be applied by the voltage, wherein the sacrificial layer is able to be directly deposited to a required thickness, or deposited to a thickness exceeding that of the anti-ferromagnetic thin film structure body and then etched back to the required thickness, such that a thickness of a etched sacrificial layer is less than or equal to that of the anti-ferromagnetic thin film structure body;
(1.4) depositing a layer of insulator isolation layer on a top and a side surface of the sacrificial layer obtained in Step (1.3);
(1.5) depositing a second electrode material on one end of the ferromagnetic thin film structure body that needs to be applied by the voltage, and performing an etching processing on the second electrode, such that the prepared second electrode has a non-overlapping part with the sacrificial layer in Step (1.3) in a top view angle, and covering the non-overlapping part with an insulator isolation layer and polishing the insulator isolation layer;
(1.6) etching and punching a hole at a position of the sacrificial layer which is not overlapped with the second electrode in Step (1.5) until the hole is in contact with the sacrificial layer, and etching away the sacrificial layer;
(1.7) depositing a VCMA electrode at a position where the sacrificial layer is etched away in Step (1.6); and
(1.8) etching away redundant VCMA electrode material at a position of the hole in Step (1.6), depositing a wire for connecting the VCMA electrode material to an exterior to obtain the VCMA electrode capable of applying the voltage to the anti-ferromagnetic thin film structure body.

9. The manufacturing method according to claim 8, wherein the VCMA electrode is prepared according to steps comprising:
(2.1) depositing the insulating layer thin film on a surface of the anti-ferromagnetic device;
(2.2) depositing the insulator isolation layer on a part of the anti-ferromagnetic device that needs not to be applied by the voltage;
(2.3) depositing the VCMA electrode on an outer side surface of the insulating layer thin film corresponding to a side surface of the anti-ferromagnetic thin film structure body of the anti-ferromagnetic device, wherein the VCMA electrode is able to be directly deposited to the required thickness, or deposited to a thickness exceeding that of the anti-ferromagnetic thin film structure body and then etched back to the required thickness, such that the thickness of the deposited VCMA electrode is less than or equal to that of the anti-ferromagnetic thin film structure body;
(2.4) performing the etching processing on the VCMA electrode deposited in Step (2.3) to form a required pattern; and
(2.5) depositing another insulator isolation layer on a top and outside surface of the VCMA electrode obtained in Step (2.4) and an outer surface of the insulating layer thin film exposed from a top of the VCMA electrode.

10. The manufacturing method according to claim 7, wherein the anti-ferromagnetic thin film structure body is able to be replaced with a ferrimagnetic thin film structure body, the ferrimagnetic thin film structure body is able to employ any one of a single-layer thin film made of a single material and a multi-layer superimposed film made of a plurality of materials.

11. The anti-ferromagnetic magnetic random access memory device according to claim 2, wherein a voltage control magnetic anisotropy (VCMA) electrode capable of applying a voltage to the anti-ferromagnetic thin film structure body for controlling magnetic anisotropy is provided around a side surface of the anti-ferromagnetic thin film structure body, and the VCMA electrode employs any one of a multilayer heterostructure made of different materials and a single structure made of a same material.

12. The anti-ferromagnetic magnetic random access memory device according to claim 3, wherein a voltage control magnetic anisotropy (VCMA) electrode capable of applying a voltage to the anti-ferromagnetic thin film structure body for controlling magnetic anisotropy is provided around a side surface of the anti-ferromagnetic thin film structure body, and the VCMA electrode employs any one of a multilayer heterostructure made of different materials and a single structure made of a same material.

13. The anti-ferromagnetic magnetic random access memory device according to claim 11, wherein an insulating layer thin film is provided around the side surface of the anti-ferromagnetic thin film structure body, and the VCMA electrode is connected to an outer surface of the insulating layer thin film by any one of connection modes, comprising completely surrounding the outer surface of the insulating layer thin film, partially surrounding the outer surface of the insulating layer thin film, and partially contacting with the outer surface of the insulating layer thin film.

14. The anti-ferromagnetic magnetic random access memory device according to claim 12, wherein an insulating layer thin film is provided around the side surface of the anti-ferromagnetic thin film structure body, and the VCMA electrode is connected to an outer surface of the insulating layer thin film by any one of connection modes, comprising completely surrounding the outer surface of the insulating layer thin film, partially surrounding the outer surface of the insulating layer thin film, and partially contacting with the outer surface of the insulating layer thin film.

15. The anti-ferromagnetic magnetic random access memory device according to claim 2, wherein the anti-ferromagnetic thin film structure body is able to be replaced with a ferrimagnetic thin film structure body, the ferrimagnetic thin film structure body employs any one of a single-layer thin film made of a single material and a multi-layer superimposed film made of a plurality of materials.

16. The anti-ferromagnetic magnetic random access memory device according to claim 3, wherein the anti-ferromagnetic thin film structure body is able to be replaced with a ferrimagnetic thin film structure body, the ferrimagnetic thin film structure body employs any one of a single-layer thin film made of a single material and a multi-layer superimposed film made of a plurality of materials.

17. The manufacturing method according to claim 7, wherein each of the ferromagnetic thin film structure body, the anti-ferromagnetic thin film structure body and the tunnel insulating thin film structure body employs any one of a single-layer thin film made of a single material and a multi-layer superimposed film made of a plurality of materials.

18. The manufacturing method according to claim 7, wherein the memory device comprises a first ferromagnetic thin film structure body, a first tunnel insulating thin film structure body arranged on an upper part of the first ferromagnetic thin film structure body, an anti-ferromagnetic thin film structure body arranged on an upper part of the first tunnel insulating thin film structure body, a second tunnel insulating thin film structure body arranged on an upper part of the anti-ferromagnetic thin film structure body, and a second ferromagnetic thin film structure body arranged on an upper part of the second tunnel insulating thin film structure body; spin electrons of the first ferromagnetic thin film structure body and the second ferromagnetic thin film structure body are fixed in opposite directions; each of the first ferromagnetic thin film structure body, the first tunnel insulating thin film structure body, the anti-ferromagnetic thin film structure body, the second tunnel insulating thin film structure body and the second ferromagnetic thin film structure body employs any one of a single-layer thin film made of a single material and a multi-layer superimposed film made of a plurality of materials.

19. The manufacturing method according to claim 7, wherein a voltage control magnetic anisotropy (VCMA) electrode capable of applying a voltage to the anti-ferromagnetic thin film structure body for controlling magnetic anisotropy is provided around a side surface of the anti-ferromagnetic thin film structure body, and the VCMA electrode employs any one of a multilayer heterostructure made of different materials and a single structure made of a same material.

20. The manufacturing method according to claim 7, wherein an insulating layer thin film is provided around the side surface of the anti-ferromagnetic thin film structure body, and the VCMA electrode is connected to an outer surface of the insulating layer thin film by any one of connection modes, comprising completely surrounding the outer surface of the insulating layer thin film, partially surrounding the outer surface of the insulating layer thin film, and partially contacting with the outer surface of the insulating layer thin film.
